(19) United States
(12) Patent Application Publication
(10) Pub. No.: US 2015/0136214 A1
(43) Pub. Date: May 21, 2015

(54) Solar cells having selective contacts and three or more terminals

(71) Applicant: The Board of Trustees of the Leland Stanford Junior University, Palo Alto, CA (US)

(72) Inventors: Raisul Islam, Palo Alto, CA (US); Gautam Shine, Stanford, CA (US); Aneesh Nainani, Palo Alto, CA (US); Krishna C. Saraswat, Saratoga, CA (US)

(21) Appl. No.: 14/549,235

(22) Filed: Nov. 20, 2014

Related U.S. Application Data
(60) Provisional application No. 61/906,850, filed on Nov. 20, 2013.

(51) Int. Cl. H01L 31/0224

(52) U.S. Cl. CPC H01L 31/022433
USPC 136/255

(57) ABSTRACT

Junction-less solar cells having three or more terminals are provided. Electron- and hole-selective contacts and interfaces are used in combination with two or more absorber layers having different bandgaps to provide multi-material solar cells that have no requirement for either lattice matching or current matching.

### CROSS REFERENCE TO RELATED APPLICATIONS

This application claims the benefit of U.S. provisional patent application 61/906,850, filed on Nov. 20, 2013, and hereby incorporated by reference in its entirety.

### GOVERNMENT SPONSORSHIP

This invention was made with Government support under contract number DE-AC36-08GO28308 awarded by the Department of Energy. The Government has certain rights in this invention.

### FIELD OF THE INVENTION

This invention relates to solar cells.

### BACKGROUND

Photovoltaic solar cells usually include a p-n junction that generates a voltage under illumination. Although most solar cells only have a single p-n junction, multi-junction solar cells have been investigated to improve device efficiency. Such approaches can improve efficiency by fabricating each p-n junction in a different material system, thereby increasing the absorption of the solar cell beyond what can be achieved in any single material. However, fabrication of such multi-junction devices can be difficult, since high quality p-n junctions are needed in each material system and lattice matching can be difficult. Furthermore, the current passing through each junction is the same, which can create difficulty for device design. For example, the most efficient operating point for each of the junctions may not have the same current. In such cases, efficiency would be compromised because each junction has the same current flowing through it.

Accordingly, it would be an advance in the art to provide an improved approach for increasing solar cell efficiency.

### SUMMARY

In this work, multi-material junction-less solar cells are considered. Instead of using p-n junctions to separate photogenerated electrons and holes from each other, electron-selective and hole-selective interfaces and contacts are used. When such a structure is illuminated, a voltage is generated in each of the active layers. Since current can enter or leave the device via intermediate terminals, the result is a three (or more) terminal multi-material solar cell having no junctions and no requirement that the same current pass through each part of the device.

Instead, a difference in current between one active layer and a neighboring active layer can be sourced or sinked by an intervening intermediate contact layer having its own terminal.

Efficiency in conventional multi-junction cells suffers from requirements on current matching and limited headroom for bandgap engineering due to requirement of lattice matching. On the other hand, approaches which involve mechanical stacking of cells on top of each other, suffer from shading losses from the top cell contacts and refractive index mismatch between air and the two cells. Using the junction-less solar cell as described herein, we can stack two (or more) of the individual junction-less cells on top of each other using a three (or more) terminal design. We can now pick the materials for each junction-less cell without any constraint on lattice matching and current matching.

The electron-selective and hole-selective contacts are provided by suitably chosen MIS (metal-insulator-semiconductor) structures, and the electron-selective and hole-selective interfaces within the active layer stack are provided by suitably chosen IS (insulator-semiconductor) structures. Although metal may be present in the interface insulator to provide sufficient electrical conductivity for current flow, as described in greater detail below, the band structure in relevant parts of the device is an IS band structure.

For a 2-terminal device, the difference in metal workfunction of the contacts gives the open circuit voltage. Using high quality crystalline material with almost no doping will increase the bulk minority carrier lifetime. The current in this case is field driven by the difference in metal workfunction rather than diffusion. Also since no doping is necessary, the total fabrication process will be very simple and possible within a low thermal budget.

As described below, this 2-terminal solar cell concept can be extended to a three or more terminal solar cell having two or more active layers of different material composition.

The present approach can provide significant advantages:

(i) Compared to selective contacts made with highly doped semiconductors, elimination of the highly doped region for contact can lower loss due to recombination in doped region.
(ii) The optimized MIS band lineup will provide a large barrier for one type of carrier while small or even zero barrier for the other type of carrier letting them pass, thereby providing substantially perfect selectivity.
(iii) Such MIS structures can provide depinning of the metal Fermi level, thereby reducing or eliminating the Schottky barrier to provide low contact resistivity. In the case where MIS contacts can provide perfect selectivity between carriers and a high level of Fermi level depinning, the use of a p-n junction becomes optional as long as proper metal with appropriate workfunction can be chosen.
(iv) This design for solar cells would reduce the diffusion step in the current process flow for the solar cells.
(v) The incorporation of interfacial oxides can get rid of highly doped regions, which act as a recombination center for minority carriers.
(vi) Fixed charge at the oxide semiconductor interface can decrease surface recombination velocity.
(vii) Since interfacial oxides have much higher bandgaps than semiconductors, they will not absorb photons.
(viii) Due to the absorption of high energy photons away from the interface, the quantum efficiency of high energy photons will be much improved.
(ix) Intrinsic semiconductor as an absorber material would ensure very high carrier lifetime and increased carrier collection. Intrinsic semiconductor will also improve performance for high concentration of light.
(x) Use of interfacial oxide eliminates the requirements of lattice matching and current matching if more than one cell are stacked on top of each other.

Reducing the $/W installed for any energy technology is important to make it commercially viable. This work provides a low cost process for making solar cells which can reduce the $/W for solar energy. The low thermal budget for making this solar cell would reduce the energy payback time, which is an important performance metric for any energy harvesting technology.

### BRIEF DESCRIPTION OF THE DRAWINGS

FIG. 1A schematically shows a metal-semiconductor with a pinned Fermi level.

FIG. 1B schematically shows an electron-selective interface.

FIG. 1C schematically shows a hole-selective interface.

FIG. 2 shows band line-ups for several materials.

FIG. 3A shows a first embodiment of the invention.

FIG. 3B shows a second embodiment of the invention.

FIGS. 4A-B schematically show band structures applicable to the example of FIG. 3A.

FIG. 4C schematically shows a band structure applicable to the example of FIG. 3B.

FIG. 5 shows an example of embedded charge to reduce recombination of carrier at selective contacts or interfaces.

### DETAILED DESCRIPTION

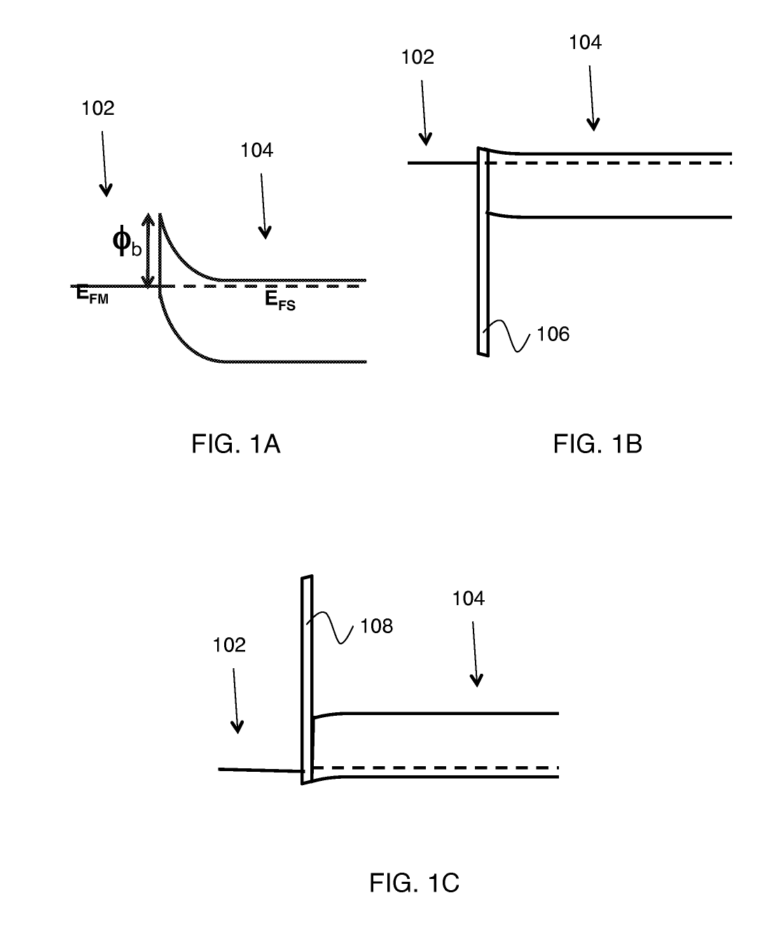

To better appreciate the present invention, it is helpful to review the band structure of a typical metal-semiconductor interface as shown on FIG. 1A. Here 102 shows the metal band structure and 104 shows the semiconductor band structure. This example shows Fermi level pinning at the metal-semiconductor interface leading to a relatively large Schottky barrier (φ_{b}.

The MIS contact shown in FIG. 1B serves as an electron selective contact where there is no barrier to electrons due to zero/negligible conduction band offset yet a large barrier to holes. An insulating layer 106 provides this desirable band configuration, as described below. The MIS contact shown in FIG. 1C serves as a hole selective contact where there is no barrier to holes due to zero/negligible valence band offset yet a large barrier to electrons. An insulating layer 108 provides this desirable band configuration, as described below. These two contact schemes provide unimpeded collection of one type of carriers and reflection of the other type of carriers due to a large band offset. Besides providing selectivity, the metal Fermi level is repinned near the conduction band edge (FIG. 1B) or the valence band edge (FIG. 1C). Fermi level repinning along with carrier selectivity of the contacts facilitates junction-less solar cell where p-n junction formation is no longer necessary to separate the electron-hole pair generated.

The main concept behind these MIS contacts is that an ultrathin insulator when inserted into the metal/semiconductor interface can block the penetration of the metal wave function into the semiconductor and equivalently reduce the metal induced gap state (MIGS) density. An additional dipole is formed at the insulator/semiconductor interface. As a result, Fermi level pinning at the metal/semiconductor Schottky junction is released and the Schottky barrier height comes to be determined by the metal work function (as opposed to being mostly independent of metal composition). When the Schottky barrier is unpinned, the barrier height can be changed by changing to a metal with a different work function.

Here we define an electron-selective contact or interface as having an energy barrier of 0.3 eV or less for electrons and an energy barrier of 1.0 eV or greater for holes. Similarly a hole-selective contact or interface has an energy barrier of 0.3 eV or less for holes and an energy barrier of 1.0 eV or greater for electrons. Preferably all contacts and interfaces have a Schottky barrier height or interface band bending of 0.3eV or less. Here we define the Schottky barrier as being the equilibrium band bending in the semiconductor as a result of the presence of the MI structure at the semiconductor surface. We have found that such small Schottky barriers can be achieved by choosing the metal and insulator compositions such that the combined effect of the metal work function and the metal-insulator Fermi level pinning provides the desired results. The bottom line is that the undesirable effects of metal-semiconductor Fermi level pinning are avoided.

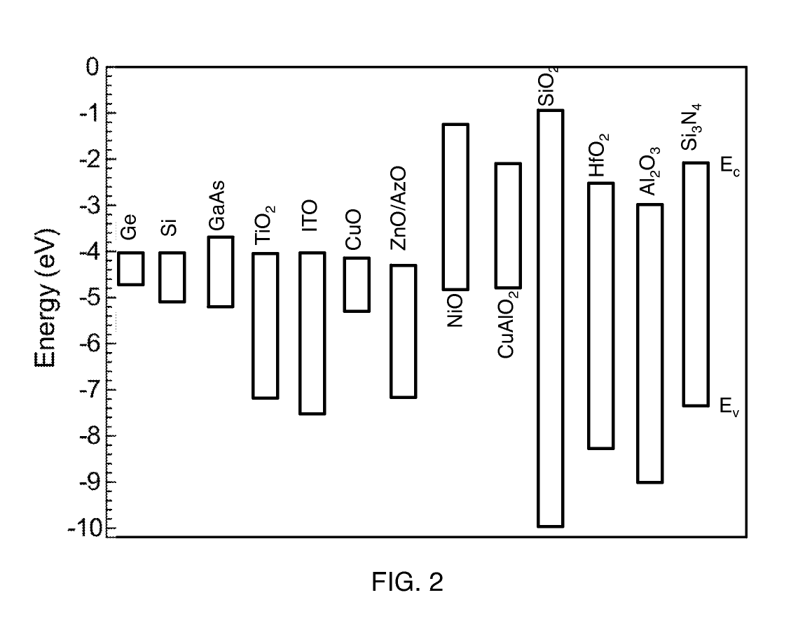

The band lineup for several different oxides along with three semiconductors Si, Ge and GaAs has been measured and is shown on FIG. 2. TiO₂ is one of the best candidates for obtaining near zero conduction band offset (CBO) to Si, Ge and GaAs as shown in FIG. 1B. Also tin oxide, indium tin oxide (ITO) and ZnO/AZO (AZO=aluminum doped zinc oxide) provide near zero conduction band offset with several semiconductors. As a result it depins the metal Fermi level without offering any tunneling resistance to electrons and provides low contact resistance. Similarly NiO and CuAlO₂ provide near zero valance band offset (VBO) with several semiconductors without offering any tunneling resistance to holes and provides low contact resistance. These materials are thus a preferred set of materials for junction-less solar cell design.

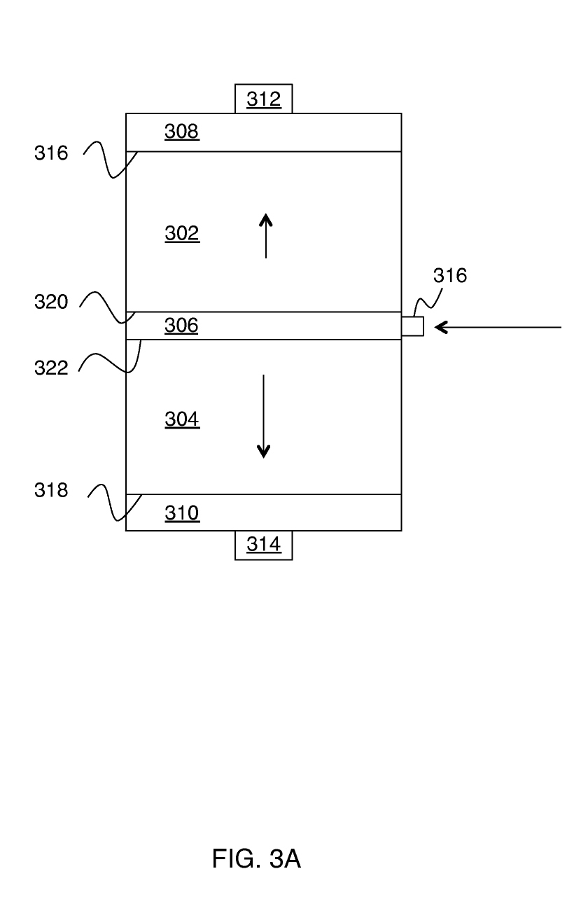

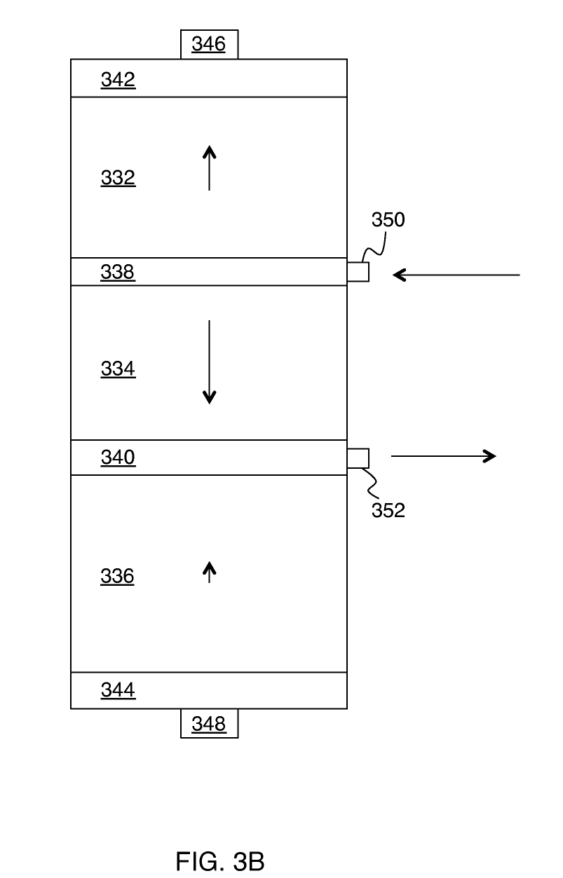

FIG. 3A shows an exemplary embodiment. Here the solar cell includes a multilayer structure having two or more absorber layers (302 and 304) and one or more intermediate contact layers (306). The absorber layers and intermediate contact layer alternate, as shown. The absorber layers are semiconductors having different bandgaps (e.g., Si and GaAs). A first contact (308 and 312) is disposed at a first surface 316 of the multilayer structure. A second contact (310 and 314) is disposed at a second surface 318 of the multilayer structure. Each intermediate contact layer has a corresponding terminal for current flow. Here intermediate contact layer 306 has terminal 316. All absorber layers have the same conductivity type (i.e., n-type, p-type, or intrinsic). In cases where intermediate contact layer 106 is not electrically conductive, or has high resistivity, metal can be embedded in this layer to facilitate current flow. If present, such metal should be configured to have minimal effect on the transparency of the intermediate contact layer. For example, a grid of thin metal embedded wires can be used, and/or the metal can be located in parts of the device that are already shaded by other structures.

Each interface within the multi-layer structure (i.e., interfaces 320 and 322) is individually either electron-selective or hole-selective. Furthermore, the first contact is either electron-selective or hole-selective, and the second contact is either electron-selective or hole-selective. Preferably the first contact is an MIS structure having an insulator 308 between semiconductor 302 and metal 312 and the second contact is an MIS structure having an insulator 310 between semiconductor 304 and metal 314. Material choices for semiconductors and insulators can be made according to the above-described principles. Metals can be selected according to the work functions they provide and their process compatibility. For electron-selective contacts, the metal work function is preferably as low as possible. For hole-selective contacts, the metal work function is preferably as high as possible.

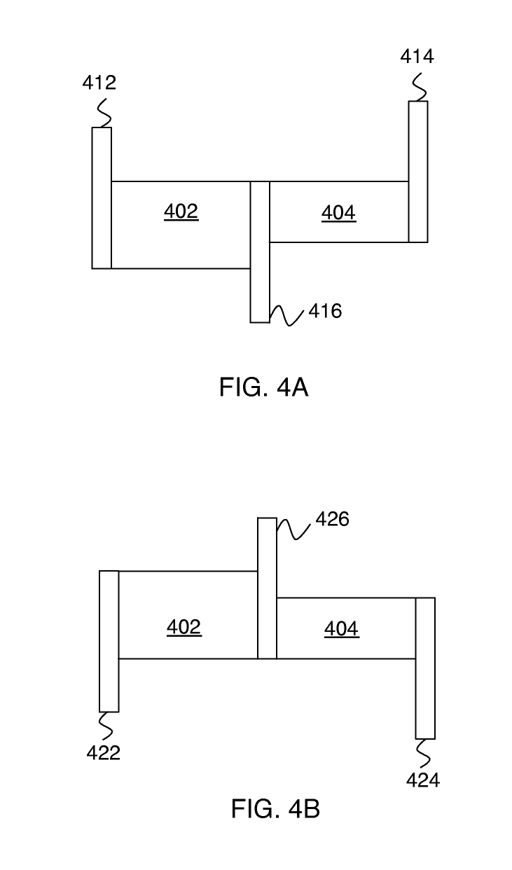

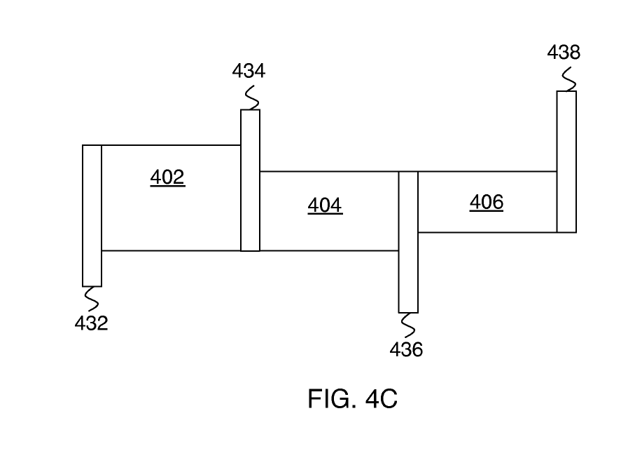

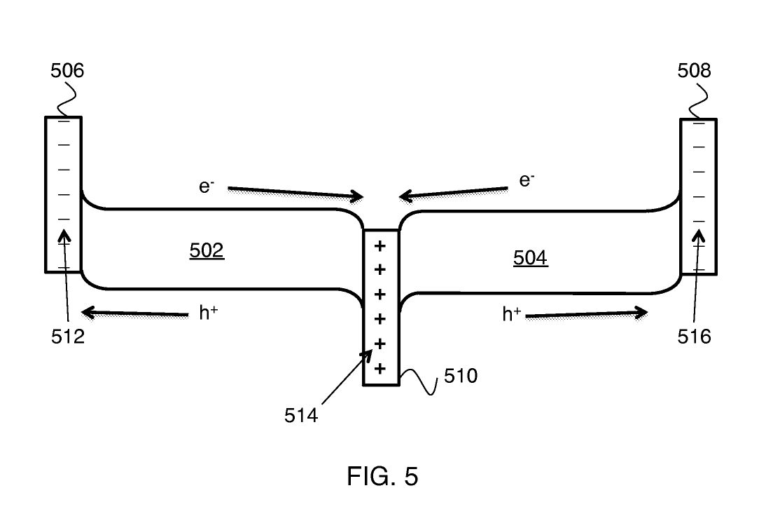

As a specific example, a first absorber layer 302 can be gallium arsenide and a second absorber layer 304 can be silicon. Intermediate contact layer 306 can be electron-selective with respect to the first and second absorber layers. The first contact (308 and 312) can be a hole-selective contact. The second contact (310 and 314) can also be a hole-selective contact. In this example, the intermediate contact layer can be selected from the group consisting of: zinc oxide, titanium oxide, aluminum-doped zinc oxide (AZO), tin oxide, and indium-doped tin oxide (ITO). In this example, the first contact includes a first contact layer 308 disposed on or in proximity to the first absorber layer, where the first contact layer 308 is selected from the group consisting of: nickel oxide and copper-aluminum oxide. In this example, the second contact includes a second contact layer 310 disposed on or in proximity to the second absorber layer, where the second contact layer is selected from the group consisting of: nickel oxide and copper-aluminum oxide. Current flow under illumination in this example is schematically shown by the arrows on FIG. 3A. Note that different currents flow in layers 302 and 304, and that terminal 316 is important for providing a way to balance current flow. Generally, current in the absorbing layer flows into the hole-selective contacts/interfaces and away from the electron-selective contacts/interfaces. With respect to the whole device, the current preferably leaves the device through the hole-selective contact(s) for power output. The resulting band structure for this example is considered below in connection with FIG. 4A.

The 2 material junction-less cell using Si and GaAs of this example can achieve a modeled efficiency of 46% under 1 sun illumination. Due to the insertion of an insulator layer in between GaAs and Si, lattice mismatch does not degrade the cell performance. Also, three terminals provide the benefit of operating without the requirement of current matching. This design is capable of showing efficiency close to 50% with only two materials. These types of structures can be fabricated using the layer transfer method widely described in the literature.

This multi-layer approach can be generalized to three or more absorbing layers. FIG. 3B shows an example. Here 332, 334 and 336 are the absorber layers, and 338 and 340 are the intermediate contact layers having corresponding terminals 350 and 352 respectively. One contact is formed by insulator 342 and metal 346, and the other contact is formed by insulator 344 and metal 348. Current flow in the device is balanced via terminals 350 and 352, and can be schematically as shown, depending on the specific materials used.

FIG. 4A schematically shows the band structure for the above-described GaAs—Si solar cell example with hole-selective contacts. Here 402 shows the GaAs bands (conduction band and valence band) and 404 show the silicon bands. The intermediate contact layer bands are shown as 416, while the insulator bands for the MIS contacts are shown as 412 and 414. FIG. 4B shows a similar example, except that the intermediate contact layer bands 426 are hole-selective with respect to semiconductors 402 and 404, and the MIS contacts are electron-selective as schematically shown by bands 422 and 424. FIG. 4C shows an example of three absorber layers (402, 404, 406), two intermediate contact layers (434, 436) and contacts 432 and 438. An alternating pattern of electron selectivity and hole selectivity is preferred.

More specifically, it is preferred that each absorbing layer in the multilayer structure have opposite-carrier selectivity at its interfaces (e.g., as shown on FIGS. 4A-C). If an absorbing layer were to have same-carrier selectivity at its interfaces, little or no voltage would be generated by such an absorbing layer upon illumination, which would significantly reduce device efficiency.

It is also preferred that each intermediate contact layer in the multilayer structure have same-carrier selectivity at its interfaces (e.g., as shown on FIGS. 4A-C).

It is preferred for such multi-material cells to have a bandgap sequence that increases from one absorbing layer to the next or decreases from one absorbing layer to the next. It is further preferred for such cells to be illuminated such that incident light passes though the higher band gap material before reaching lower band gap materials. Thus, on FIGS. 4A-C, it is preferred for illumination to be from the left in all three cases shown.

Fixed charges can be included in the insulating part of an MIS contact to reduce recombination. An electron-selective contact can include an insulating layer having fixed positive charge to repel holes from the electron-selective contact, thereby reducing hole recombination at the electron-selective contact. Similarly, a hole-selective contact can include an insulating layer having fixed negative charge to repel electrons from the hole-selective contact, thereby reducing electron recombination at the hole-selective contact. FIG. 5 shows an example of this approach. In this example, absorber layers 502 and 504 sandwich an intermediate contact layer 510. Contacts 506 and 508 are disposed at the ends of the device. Contacts 506 and 508 are hole-selective and include fixed negative charge 512 and 516 to repel electrons from the contacts. Intermediate contact layer 510 is electron-selective, and includes fixed positive charge 514 to repel holes from its interfaces. The incorporation of fixed charge into the insulator is possible during the deposition process.

Preferably, the first and second contacts are both transparent, and each of the intermediate contact layers is also transparent. As indicated above, metal can be included in such contacts and intermediate layers if necessary to provide sufficient electrical conductivity, provided the transparency is not unduly reduced.

1. A solar cell comprising:
a multilayer structure having two or more absorber layers and one or more intermediate contact layers, wherein the absorber layers and the intermediate contact layers alternate, and wherein the absorber layers are semiconductors having different band gaps;
a first contact disposed at a first surface of the multilayer structure;
a second contact disposed at a second surface of the multilayer structure opposite the first surface;
wherein each intermediate contact layer within the multilayer structure has a corresponding terminal for current flow;
wherein all absorber layers of the multilayer structure have the same conductivity type;
wherein each interface within the multilayer structure is individually either electron-selective or hole-selective;
wherein the first contact is either electron-selective or hole-selective; and
wherein the second contact is either electron-selective or hole-selective.

2. The solar cell of claim 1, wherein an interface or contact is electron-selective if it provides an energy barrier of 0.3 eV or less for electrons and an energy barrier of 1.0 eV or greater for holes.

3. The solar cell of claim 1, wherein an interface or contact is hole-selective if it provides an energy barrier of 0.3 eV or less for holes and an energy barrier of 1.0 eV or greater for electrons.

4. The solar cell of claim 1, wherein the first contact is configured to provide a Schottky barrier of 0.3 eV or less at the first surface.

5. The solar cell of claim 1, wherein the second contact is configured to provide a Schottky barrier of 0.3 eV or less at the second surface.

6. The solar cell of claim 1, wherein the multilayer structure is configured to provide a Schottky barrier of 0.3 eV or less at interfaces within the multilayer structure.

7. The solar cell of claim 1,
wherein a first absorber layer is gallium arsenide,
wherein a second absorber layer is silicon,
wherein a first intermediate contact layer is electron-selective with respect to the first and second absorber layers;
wherein the first contact is a hole-selective contact; and
wherein the second contact is a hole-selective contact.

8. The solar cell of claim 7, wherein the intermediate contact layer is selected from the group consisting of: zinc oxide, titanium oxide, aluminum-doped zinc oxide (AZO), tin oxide, and indium-doped tin oxide (ITO).

9. The solar cell of claim 7, wherein the first contact comprises a first contact layer disposed on or in proximity to the first absorber layer, and wherein the first contact layer is selected from the group consisting of: nickel oxide and copper-aluminum oxide.

10. The solar cell of claim 7, wherein the second contact comprises a second contact layer disposed on or in proximity to the second absorber layer, and wherein the second contact layer is selected from the group consisting of: nickel oxide and copper-aluminum oxide.

11. The solar cell of claim 1, wherein each absorbing layer in the multilayer structure has opposite-carrier selectivity at its interfaces.

12. The solar cell of claim 11, wherein each intermediate contact layer in the multilayer structure has same-carrier selectivity at its interfaces.

13. The solar cell of claim 1, wherein the first and second contacts are both transparent, and wherein each of the intermediate contact layers is transparent, whereby the solar cell can receive light from both sides of the solar cell.

14. The solar cell of claim 1, wherein an electron-selective contact includes a layer having fixed positive charge to repel holes from the electron-selective contact, whereby hole recombination at the electron-selective contact is reduced.

15. The solar cell of claim 1, wherein a hole-selective contact includes a layer having fixed negative charge to repel electrons from the hole-selective contact, whereby electron recombination at the hole-selective contact is reduced.

16. The solar cell of claim 1, wherein all absorber layers of the multilayer structure are either: intrinsic, n-type or p-type.
